(19) United States
(12) Patent Application Publication
(10) Pub. No.: US 2023/0042099 A1
(43) Pub. Date: Feb. 9, 2023

(54) FILM FORMATION METHOD AND FILM FORMATION APPARATUS

(71) Applicant: Tokyo Electron Limited, Minato-ku, Tokyo (JP)

(72) Inventors: Makoto WADA, Nirasaki City, Yamanashi (JP); Takashi MATSUMOTO, Nirasaki City, Yamanashi (JP); Nobutake KABUKI, Nirasaki City, Yamanashi (JP); Ryota IFUKU, Nirasaki City, Yamanashi (JP); Masahito SUGIURA, Nirasaki City, Yamanashi (JP); Hirokazu UEDA, Nirasaki City, Yamanashi (JP)

(21) Appl. No.: 17/757,906

(22) PCT Filed: Nov. 26, 2020
(86) PCT No.: PCT/JP2020/044009

§ 371 Date: Jun. 23, 2022

(30) Foreign Application Priority Data
Dec. 26, 2019 (JP) 2019-236943

(51) Int. Cl. C23C 16/44; H01J 37/32; H01L 21/768; H01L 21/285; C23C 16/26; C23C 16/511; C01B 32/186

(52) U.S. Cl. CPC C23C 16/4405; H01J 37/32862; H01L 21/76841; H01L 21/28556; C23C 16/26; C23C 16/511; C01B 32/186; H01J 2237/3321; H01J 37/32192; H01J 37/32522; H01J 37/32834

(57) ABSTRACT

A film forming method of forming a carbon film includes: cleaning an interior of a processing container by using oxygen-containing plasma in a state in which no substrate is present inside the processing container; subsequently, extracting and removing oxygen inside the processing container by using plasma in the state in which no substrate is present inside the processing container; and subsequently, loading a substrate into the processing container and forming the carbon film on the substrate through plasma CVD using a processing gas including a carbon-containing gas, wherein the cleaning, the extracting and removing the oxygen, and the forming the carbon film are repeatedly performed.

### TECHNICAL FIELD

The present disclosure relates to a film forming method and a film forming apparatus.

### BACKGROUND

Carbon, especially graphene, is a material expected to be applied to various applications, and as a manufacturing method thereof, forming a film on a substrate by using a plasma chemical vapor deposition (CVD) method is known (e.g., Patent Documents 1 and 2).

### PRIOR ART DOCUMENTS

### Patent Documents

Patent Document 1: Japanese Laid-Open Patent Publication No. 2014-167142

Patent Document 2: Japanese Laid-Open Patent Publication No. 2019-55887

### SUMMARY

The present disclosure provides a film forming method and a film forming apparatus capable of suppressing influence of residual oxygen when forming a carbon film and influence of oxygen on a surface of a substrate to be processed before forming the carbon film.

A film forming method according to an aspect of the present disclosure is a film forming method of forming a carbon film by a plasma CVD apparatus. The film forming method includes: cleaning an interior of a processing container by using oxygen-containing plasma in a state in which no substrate is present inside the processing container; subsequently, extracting and removing oxygen inside the processing container by using plasma in the state in which no substrate is present inside the processing container; and subsequently, loading a substrate into the processing container and forming the carbon film on the substrate through plasma CVD using a processing gas including a carbon-containing gas, wherein the cleaning, the extracting and removing the oxygen, and the forming the carbon film are repeatedly performed.

According to the present disclosure, a film forming method and a film forming apparatus, which are capable of suppressing influence of residual oxygen when forming a carbon film and influence of oxygen on a surface of a substrate to be processed before forming the carbon film, are provided.

### BRIEF DESCRIPTION OF DRAWINGS

FIG. 1 is a cross-sectional view illustrating a first example of a processing apparatus appropriate for carrying out a film forming method according to an embodiment.

FIG. 2 is a configuration diagram illustrating a configuration of a microwave introduction device in the processing apparatus of FIG. 1.

FIG. 3 is a cross-sectional view schematically illustrating a microwave radiation mechanism in the processing apparatus of FIG. 1.

FIG. 4 is a bottom view schematically illustrating a ceiling wall of a processing container in the processing apparatus of FIG. 1.

FIG. 5 is a cross-sectional view illustrating a second example of a processing apparatus appropriate for carrying out a film forming method according to an embodiment.

FIG. 6 is a flowchart illustrating a film forming method according to a first embodiment.

FIG. 7 is a cross-sectional view illustrating a structural example of a semiconductor device when a graphene film is applied to a contact barrier layer.

FIG. 8 is a view illustrating a state in which a cleaning process is performed in the film forming apparatus of FIG. 1.

FIG. 9 is a view illustrating a state in which a graphene film is formed just after a cleaning process in the film forming apparatus of FIG. 1.

FIG. 10 is a view illustrating a state in which oxygen in the processing container is extracted and removed by using plasma after a cleaning process in the film forming apparatus of FIG. 1.

FIG. 11 is a view showing confirmation results of effects when a process of extracting and removing oxygen in the processing container by using plasma was performed by using Ar—H₂ plasma.

FIG. 12 is a view showing a confirmation result of effects when the process of extracting and removing oxygen in the processing container by using plasma was performed by using N₂ plasma.

FIG. 13 is a view showing an analysis result of a surface oxidation state of a poly-Si film after a graphene film was formed on a substrate having the poly-Si film formed on a Si base, wherein FIG. 13 illustrates a case in which the process of extracting and removing oxygen was applied and a case in which the process of extracting and removing oxygen was not applied.

FIG. 14 is a flowchart illustrating a film forming method according to a second embodiment.

FIG. 15 is a view illustrating a state in which a carbon film is precoated on the film forming apparatus of FIG. 1.

### DETAILED DESCRIPTION

Hereinafter, embodiments will be described in detail with reference to the accompanying drawings.

### <Background >

When forming a graphene film as a carbon film, since a surface of a substrate (e.g., a Si base itself or a poly-Si film) as a base has a natural oxide film, film formation is performed after removing the natural oxide film by wet etching. However, when oxygen, moisture, and OH are residually adsorbed on a side wall of a processing container at the time of forming the graphene film, they bond to oxygen or moisture in a processing container by a reaction accompanied by plasma irradiation or heating and easily reoxidize the surface of the substrate. When a temperature of the substrate at the time of film formation is set to a high temperature of, for example, 400 degrees C. or higher in order to form high-quality and low-defect graphene, an oxide film is more likely to be formed. In addition, since a temperature inside the processing container is set to a film forming temperature even before the film formation, an oxidation reaction occurs at the time of transporting the substrate into the processing container or at the time of preprocessing the substrate before the film formation. Therefore, when forming a graphene film, it is important to reduce an amount of oxygen in the processing container as much as possible.

On the other hand, a carbon film such as a graphene film is conventionally formed through a plasma CVD method, but carbon adheres to an inner wall of a processing container of a film forming apparatus due to the plasma CVD film formation. Therefore, as described in Patent Document 2, a film forming apparatus is configured to be capable of supplying O₂ gas, which is an oxidation gas as a cleaning gas, into the processing container. That is, the carbon adhering to the inner wall of the processing container is oxidized and removed by a plasma cleaning process using an oxygen-containing gas such as O₂ gas, and such a plasma cleaning process and a film forming process are repeatedly performed.

However, since the plasma cleaning process is performed by using the oxygen-containing gas such as O₂, oxygen is introduced into a surface and the inside of the inner wall of the processing container through the cleaning process. In addition, a base material of the processing container is over-oxidized and oxygen may remain on the surface of the processing container as a reactant. Therefore, when a substrate is loaded into the processing container in such a state and a graphene film is formed, a surface of the substrate is easily reoxidized. In addition, oxygen is also introduced into the graphene film itself.

Therefore, in an embodiment, after the plasma cleaning process, a plasma process of extracting and removing oxygen in the processing container is performed, and then a graphene film is formed. This makes it possible to effectively suppress influences of oxygen such as oxidation of a surface of a substrate during formation of a graphene film and introduction of oxygen into the film. Similar effects can be obtained when forming a carbon film other than the graphene film, for example, an amorphous carbon film or a diamond-like carbon film.

### First Embodiment

Next, a first embodiment will be described.

In the first embodiment, a plasma CVD apparatus is used as a film forming apparatus to form a graphene film as a carbon film. The plasma CVD apparatus is not particularly limited, but a microwave plasma CVD apparatus is desirable. Microwave plasma is plasma with high radical density and low electron temperature. Thus, microwave plasma shows high processing efficiency with low damage. Therefore, it is possible to directly form a graphene film on a Si substrate, an insulating film, a silicon film, or a metallic film without damaging a substrate or the graphene film itself.

First, an example of a desirable film forming apparatus to which such a microwave plasma CVD apparatus is applied will be described.

[First Example of Film Forming Apparatus]

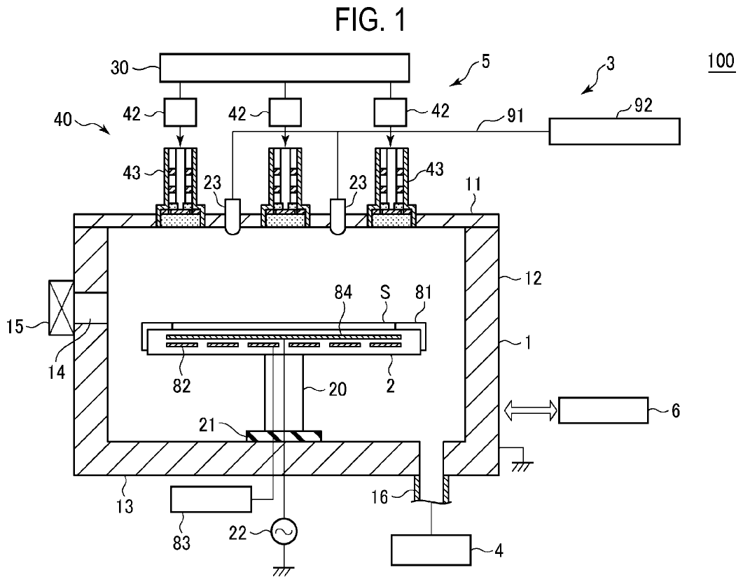

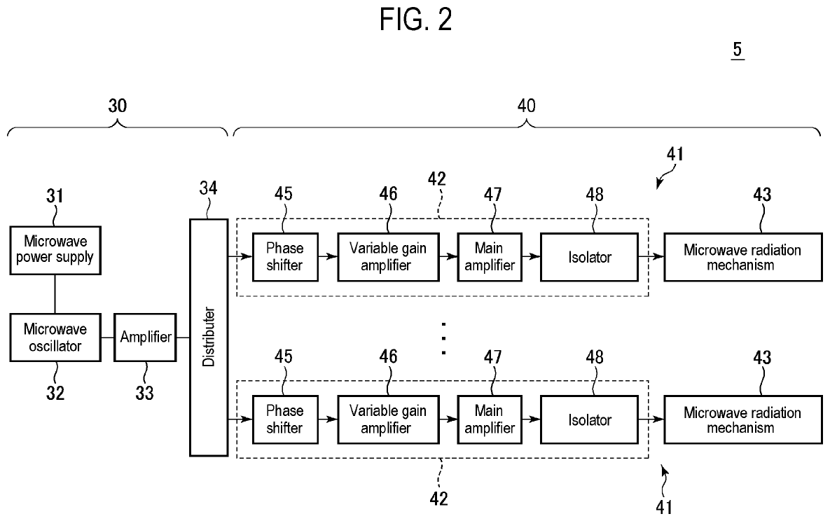

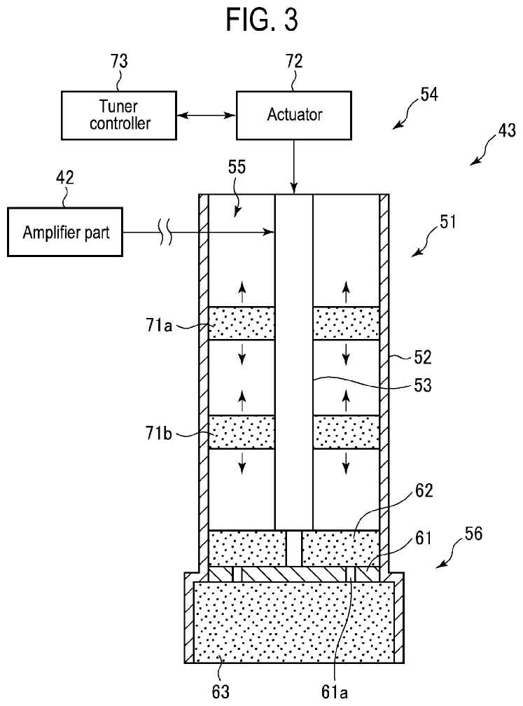

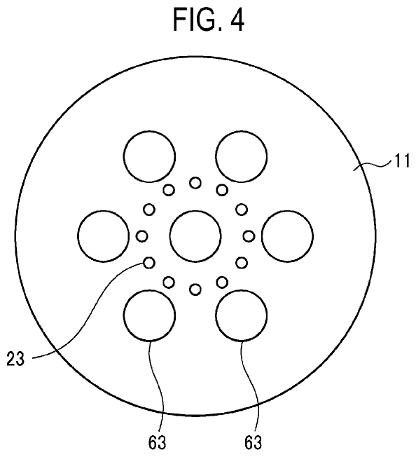

FIG. 1 is a cross-sectional view schematically illustrating a first example of a film forming apparatus. FIG. 2 is a configuration diagram illustrating a configuration of a microwave introduction device of the film forming apparatus of FIG. 1. FIG. 3 is a cross-sectional view schematically illustrating a microwave radiation mechanism in the film forming apparatus of FIG. 1. FIG. 4 is a bottom view schematically illustrating a ceiling wall of a processing container in the film forming apparatus of FIG. 1.

A film forming apparatus 100 includes a processing container 1, a stage 2, a gas supply 3, an exhaust device 4, a microwave introduction device 5, and a controller 6.

The processing container 1 accommodates a substrate S, and is formed of, for example, a metallic material such as aluminum or an alloy thereof. The processing container 1 has a substantially cylindrical shape, and includes a plate-shaped ceiling wall 11, a plate-shaped bottom wall 13, and a side wall 12 interconnecting the ceiling wall 11 and the bottom wall 13. Inner surfaces of the ceiling wall 11 and the side wall 12 constitute an inner wall of the processing container 1. When the processing container 1 is made of Al, the processing container 1 may have an Al₂O₃ film for preventing arcing on a surface thereof In addition, a ceramic coat such as Al₂O₃ or Y₂O₃ may be formed on a surface of the inner wall.

The microwave introduction device 5 is provided above the processing container 1, and functions as a plasma generator that introduces electromagnetic waves (microwaves) into the processing container 1 so as to generate plasma. The microwave introduction device 5 will be described in detail later.

The ceiling wall 11 has a plurality of openings into which microwave radiation mechanisms and gas introducer of the microwave introduction device 5, which will be described later, are inserted and fitted. The side wall 12 has a loading/unloading port 14 for performing loading and unloading of the substrate S therethrough with respect to a transport chamber (not illustrated) adjacent to the processing container 1. The loading/unloading port 14 is configured to be opened and closed by a gate valve 15. The bottom wall 13 is provided with an exhaust device 4. The exhaust device 4 is provided in an exhaust pipe 16 connected to the bottom wall 13 and includes a vacuum pump and a pressure control valve. By the vacuum pump of the exhaust device 4, a gas inside the processing container 1 is exhausted via the exhaust pipe 16. A pressure inside the processing container 1 is controlled by the pressure control valve.

The stage 2 is disposed inside the processing container 1, and the substrate S is placed thereon. The stage 2 has a disk shape and is made of ceramic such as AlN. The stage 2 is supported by a cylindrical support 20 made of ceramic, such as AlN, and extending upward from a center of a bottom of the processing container 1. A guide ring 81 configured to guide the substrate S is provided on an outer edge of the stage 2. In addition, lifting pins (not illustrated) for raising and lowering the substrate S are provided inside the stage 2 so as to be capable of protruding and retracting with respect to a top surface of the stage 2. In addition, a resistance heating type heater 82 is embedded inside the stage 2. The heater 82 heats the substrate S on the stage 2 via the stage 2 by being fed with power from a heater power supply 83. A thermocouple (not illustrated) is inserted into the stage 2, and the stage 102 is configured to be capable of controlling a heating temperature of the substrate S to a predetermined temperature within a range of, for example, 350 to 1,000 degrees C., based on a signal from the thermocouple. In addition, an electrode 84 having a size similar to that of the substrate S is embedded above the heater 82 in the stage 2, and a radio-frequency bias power supply 22 is electrically connected to the electrode 84. Radio-frequency bias power for attracting ions is applied from the radio-frequency bias power supply 22 to the stage 2. The radio-frequency bias power supply 22 may not be provided, depending on characteristics of a plasma processing.

The gas supply 3 is for supplying a plasma generating gas (a rare gas such as Ar gas), a raw material gas for forming a graphene film, a gas for cleaning the interior of the processing container 1, a gas for removing oxygen in the processing container 1, and the like into the processing container 1. The gas supply 3 includes a gas supply mechanism 92 that includes a plurality of gas sources for supplying the above-described gases, pipes connected to the respective gas sources, and valves and flow rate controllers provided in the pipes, or the like. The gas supply 3 further includes a common pipe 91 that guides a gas from the gas supply mechanism 92, and a plurality of gas introduction nozzles 23 connected to the pipe 91. Each of the gas introduction nozzles 23 is inserted and fitted into the opening formed in the ceiling wall 11 of the processing container 1, and the gas from the gas supply mechanism 92 are introduced into the processing container 1 via the pipe 91 and the gas introduction nozzles 23. In addition, dissociation of gases may be adjusted by providing a shower plate between the ceiling wall 11 and the stage 2, or by lengthening the gas introduction nozzles downward to supply a raw material gas for film formation and the like to a position near the substrate S.

As described above, the microwave introduction device 5 is provided above the processing container 1, and functions as a plasma generator that introduces electromagnetic waves (microwaves) into the processing container 1 to generate plasma. As illustrated in FIG. 1, the microwave introduction device 5 includes the ceiling wall 11 of the processing container 1 that functions as a ceiling plate, a microwave output part 30, and an antenna unit 40.

The microwave output part 30 generates microwaves, and distributes and outputs the microwaves to a plurality of paths. As illustrated in FIG. 2, the microwave output part 30 includes a microwave power supply 31, a microwave oscillator 32, an amplifier 33, and a distributor 34. The microwave oscillator 32 is a solid-state oscillator and oscillates microwaves at, for example, 860 MHz (e.g., PLL oscillation). A frequency of the microwaves is not limited to 860 MHz, and may be a frequency within a range of 700 MHz to 10 GHz, such as 2.45 GHz, 8.35 GHz, 5.8 GHz, 1.98 GHz, and the like. The amplifier 33 amplifies the microwaves oscillated by the microwave oscillator 32. The distributor 34 distributes the microwaves amplified by the amplifier 33 to a plurality of paths, and is configured to distribute the microwaves while matching impedances on an input side and an output side.

The antenna unit 40 introduces the microwaves output from the microwave output part 30 into the processing container 1. As illustrated in FIG. 2, the antenna unit 40 includes a plurality of antenna modules 41. Each of the plurality of antenna modules 41 introduces the microwaves distributed by the distributor 34 into the processing container 1. Configurations of all of the antenna modules 41 are the same. Each antenna module 41 includes an amplifier part 42 configured mainly to amplify the distributed microwaves and output the amplified microwaves, and a microwave radiation mechanism 43 configured to radiate the microwaves output from the amplifier part 42 into the processing container 1.

The amplifier part 42 includes a phase shifter 45, a variable gain amplifier 46, a main amplifier 47, and an isolator 48. The phase shifter 45 changes a phase of the microwaves. The variable gain amplifier 46 adjusts a power level of the microwaves input to the main amplifier 47. The main amplifier 47 is configured as a solid-state amplifier. The isolator 48 separates reflected microwaves, which are reflected from an antenna part of the microwave radiation mechanism 43, which will be described later, and are directed towards the main amplifier 47.

As illustrated in FIG. 1, the plurality of microwave radiation mechanisms 43 is provided on the ceiling wall 11. In addition, as illustrated in FIG. 3, each microwave radiation mechanism 43 includes a coaxial tube 51, a feeding part 55, a tuner 54, and an antenna part 56. The coaxial tube 51 includes a cylindrical outer conductor 52, an inner conductor 53 provided inside the outer conductor 52 coaxially with the outer conductor 52, and a microwave transmission path between the outer conductor 52 and the inner conductor 53.

The feeding part 55 feeds the amplified microwaves from the amplifier part 42 to the microwave transmission path. The microwaves amplified by the amplifier part 42 are introduced into the feeding part 55 from a lateral side of an upper end portion of the outer conductor 52 via a coaxial cable. For example, by radiating the microwaves from a feeding antenna, microwave power is fed to the microwave transmission path between the outer conductor 52 and the inner conductor 53 and propagates toward the antenna part 56.

The antenna part 56 radiates the microwaves from the coaxial tube 51 into the processing container 1, and is provided at a lower end portion of the coaxial tube 51. The antenna part 56 includes a planar antenna 61, which is connected to the lower end portion of the inner conductor 53 and has a disk shape, a slow-wave member 62 disposed on a top surface of the planar antenna 61, and a microwave transmission plate 63 disposed on a bottom surface of the planar antenna 61. The microwave transmission plate 63 is inserted and fitted into the ceiling wall 11, and a bottom surface of the microwave transmission plate 63 is exposed to an internal space of the processing container 1. The planar antenna 61 has slots 61a penetrating the planar antenna 61. A shape of the slots 61a is appropriately set such that microwaves are efficiently radiated. A dielectric material may be inserted into each slot 61a. The slow-wave member 62 is formed of a material having a dielectric constant greater than that of a vacuum, and the phase of microwaves can be adjusted based on a thickness of the slow-wave member 62 so that radiation energy of the microwaves can be maximized. The microwave transmission plate 63 is also made of a dielectric material, and has a shape capable of efficiently radiating microwaves in a TE mode. The microwaves transmitted through the microwave transmission plate 63 generate plasma in the internal space of the processing container 1. As a material for constituting the slow-wave member 62 and the microwave transmission plate 63, for example, quartz, ceramic, or a fluorine-based resin, such as a polytetrafluoroethylene resin or a polyimide resin, may be used.

The tuner 54 matches an impedance of a load with a characteristic impedance of the microwave power supply 31. The tuner 54 constitutes a slug tuner. For example, as illustrated in FIG. 3, the tuner 54 includes two slugs 71a and 71b, an actuator 72 configured to independently drive these two slugs, and a tuner controller 73 configured to control the actuator 72. The slugs 71a and 71b are disposed in a portion closer to a proximal end (upper end) of the coaxial tube 51 than the antenna part 56.

The slugs 71a and 71b have a planar or annular plate shape, and are made of a dielectric material such as ceramic. The slogs 71a and 71b are disposed between the outer conductor 52 and the inner conductor 53 of the coaxial tube 51. In addition, the actuator 72 individually drives the slugs 71a and 71b by, for example, rotating two screws that are screw-coupled to the slugs 71a and 71b, respectively. In addition, based on a command from the tuner controller 73, the actuator 72 moves the slugs 71a and 71b vertically. The tuner controller 73 adjusts positions of the slugs 71a and 71b such that an impedance at a terminal end portion becomes 50Ω.

The main amplifier 47, the tuner 54, and the planar antenna 61 are disposed close to one another. The tuner 54 and the planar antenna 61 constitute a lumped constant circuit, and also function as a resonator. Impedance mismatch exists in a portion where the planar antenna 61 is installed. However, since the impedance mismatch is directly tuned by the tuner 54 with respect to a plasma load, it is possible to tune the impedance mismatch including plasma with high precision. Therefore, influence of reflection in the planar antenna 61 can be eliminated.

As illustrated in FIG. 4, in this example, seven microwave radiation mechanisms 43 are provided, and microwave transmission plates 63 corresponding to the same are evenly disposed to form a hexagonal closest-packed arrangement. That is, one of the seven microwave transmission plates 63 is disposed at the center of the ceiling wall 11, and the other six microwave transmission plates 63 are disposed therearound. These seven microwave transmission plates 63 are disposed at equidistant intervals from adjacent ones of the microwave transmission plates. In addition, the plurality of nozzles 23 of the gas supply 3 are disposed to surround a periphery of the central microwave transmission plate. The number of microwave radiation mechanisms 43 is not limited to seven.

The controller 6 is typically configured with a computer, and controls respective components of the film forming apparatus 100. The controller 6 includes, for example, a storage, which stores a process sequence of the film forming apparatus 100 and process recipes as control parameters, an input part, and a display, and is capable of performing a predetermined control according to a selected process recipe.

In the film forming apparatus 100, as will be described later, all of a cleaning process in the processing container, an oxygen removing process in the processing container, and a film forming process are performed by microwave plasma.

When a process with microwave plasma is performed by the film forming apparatus 100, a rare gas such as Ar gas is supplied as a plasma generating gas from the gas introduction nozzles 23 to a portion directly under the ceiling wall 11 of the processing container 1, and microwaves are radiated into the processing container 1 to ignite plasma. As for the radiation of the microwaves, microwaves output from the microwave output part 30 of the microwave introduction device 5 in a distributed manner are guided into the plurality of antenna modules 41 of the antenna unit 40 and radiated from the microwave radiation mechanisms 43.

In each antenna module 41, the microwaves are individually amplified by the main amplifier 47 constituting the solid-state amplifier, fed to each microwave radiation mechanism 43, and transmitted along the coaxial tube 51 to reach the antenna part 56. At that time, the impedance of the microwaves is automatically matched by the slugs 71a and 71b of the tuner 54. Therefore, in a state in which there is substantially no power reflection, the microwaves pass through the slow-wave member 62 of the antenna part 56 from the tuner 54, and are radiated from the slots 61a in the planar antenna 61. Then, the microwaves further pass through the microwave transmission plate 63 and are transmitted along a surface (bottom surface) of the microwave transmission plate 63, which is in contact with the plasma, thereby forming surface waves. Power from each antenna part 56 is spatially synthesized in the processing container 1, and surface wave plasma is generated by a rare gas such as Ar gas in a region directly below the ceiling wall 11. This region becomes a plasma generation region.

Then, at the timing at which the plasma is ignited, processing gases required for the cleaning process, the oxygen removing process, and the film forming process are supplied from the gas supply mechanism 92 via the gas introduction nozzles 23, and plasma processes corresponding to these processes is performed.

In addition, the plasma generating gas and the processing gases may be simultaneously supplied to the plasma generation region to ignite the plasma, or the processing gases may be supplied to the plasma generation region to ignite the plasma by itself without using the plasma generating gas.

### [Second Example of Film Forming Apparatus]

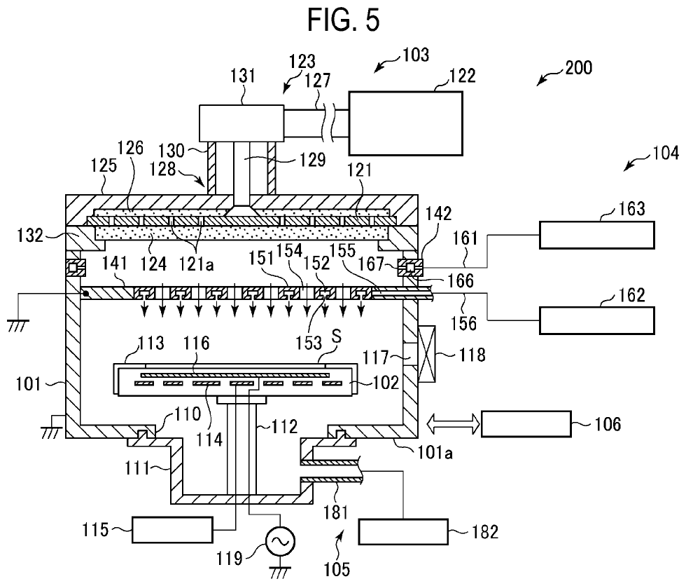

FIG. 5 is a cross-sectional view schematically illustrating a second example of the film forming apparatus. A film forming apparatus 200 illustrated in FIG. 5 is configured as, for example, an RLSA (registered trademark) microwave plasma-type plasma processing apparatus.

The film forming apparatus 200 includes a processing container 101, a stage 102, a microwave introduction mechanism 103, a gas supply 104, an exhauster 105, and a controller 106.

The processing container 101 accommodates a substrate S, and is formed of, for example, a metallic material such as aluminum or an alloy thereof. The processing container 101 has a substantially cylindrical shape. An inner surfaces of a ceiling wall and a side wall of the processing container constitute an inner wall of the processing container 101. When the processing container 101 is made of Al, the processing container 1 may have an Al₂O₃ film for preventing arcing on a surface thereof. In addition, a ceramic coat such as Al₂O₃ or Y₂O₃ may be formed on a surface of the inner wall. p A circular opening 110 is formed in a substantially central portion of a bottom wall 101a of the processing container 101, and the bottom wall 101a is provided with an exhaust chamber 111 that communicates with the opening 110 and protrudes downward. The side wall of the processing container 101 is provided with a loading/unloading port 117 for loading and unloading the substrate S and a gate valve 118 for opening and closing the loading/unloading port 117.

The stage 102 is provided inside the processing container 101, and the substrate S is placed thereon. The stage 2 is disk-shaped, and made of ceramic such as AlN. The stage 102 is supported by a cylindrical support 112 that are made of ceramic such as AlN and extends upward from a center of a bottom of the exhaust chamber 111. A guide ring 113 configured to guide the substrate S is provided on an outer edge of the stage 102. In addition, lifting pins (not illustrated) for raising and lowering the substrate S are provided inside the stage 102 so as to be capable of protruding and retracting with respect to a top surface of the stage 102. In addition, a resistance heating type heater 114 is embedded inside the stage 102. The heater 114 is fed with power from a heater power supply 115 and heats the substrate S via the stage 102. A thermocouple (not illustrated) is inserted into the stage 102, and the stage 102 is configured to be capable of controlling a heating temperature of the substrate S to a predetermined temperature within a range of, for example, 300 to 1,000 degrees C., based on a signal from the thermocouple. In addition, an electrode 116 having a size similar to that of the substrate S is embedded above the heater 114 in the stage 102, and a radio-frequency bias power supply 119 is electrically connected to the electrode 116. Radio-frequency bias power for attracting ions is applied from the radio-frequency bias power supply 119 to the stage 102. The radio-frequency bias power supply 119 may not be provided, depending on characteristics of a plasma processing.

The microwave introduction mechanism 103 is configured to introduce microwaves into the processing container 101, and is provided to face an upper opening of the processing container 101. The microwave introduction mechanism 103 includes a planar slot antenna 121, a microwave generator 122, and a microwave transmission mechanism 123.

The planar slot antenna 121 is made of, for example, a copper or aluminum plate having a silver-plated or gold-plated surface, and a plurality of slots 121a for radiating microwaves penetrates the planar slot antenna 121 in a predetermined pattern. The pattern of the slots 121a is appropriately set such that the microwaves are evenly radiated. An example of an appropriate pattern includes a radial line slot, in which two slots 121a arranged in a T shape form a pair and a plurality of pairs of slots 121a is concentrically arranged. A length and arrangement intervals of the slots 121a are appropriately determined depending on an effective wavelength λg of the microwaves. In addition, the slots 121a may have another shape, such as a circular shape or an arc shape. The arrangement form of the slots 121a is not particularly limited, and the slots 121a may be arranged, for example, in a spiral shape or a radial shape, in addition to the concentric circle shape. The pattern of the slots 121a is appropriately set to have a microwave radiation characteristic that is capable of obtaining a desired plasma density distribution.

A microwave transmission plate 124 made of a dielectric material is provided below the planar slot antenna 121 so as to be supported by a ring-shaped upper plate 132 provided in an upper portion of the processing container 101. In addition, a water-cooling type shield member 125 is provided on the planar slot antenna 121. In addition, a slow-wave member 126 is provided between the shield member 125 and the planar slot antenna 121.

The slow-wave member 126 is made of a dielectric material having a dielectric constant greater than that of a vacuum, for example, quartz, ceramic (Al₂O₃), or a resin such as polytetrafluoroethylene or polyimide. The slow-wave member 126 functions to make a wavelength of the microwaves shorter than that in a vacuum, thereby reducing a size of the planar slot antenna 121. The microwave transmission plate 124 is also made of the same dielectric material.

Thicknesses of the microwave transmission plate 124 and the slow-wave member 126 are adjusted such that an equivalent circuit formed by the slow-wave member 126, the planar slot antenna 121, the microwave transmission plate 124, and plasma satisfies a resonance condition. By adjusting the thickness of the slow-wave member 126, it is possible to adjust a phase of the microwaves. By adjusting the thicknesses such that a joint portion of the planar slot antenna 121 becomes an “antinode” of a standing wave, reflection of the microwaves is minimized and radiation energy of the microwaves is maximized. In addition, when the slow-wave member 126 and the microwave transmission plate 124 are made of the same material, it is possible to prevent interface reflection of the microwaves.

The microwave generator 122 is configured to generate microwaves, and includes a microwave oscillator. The microwave oscillator may be a magnetron oscillator or a solid-state oscillator. A frequency of microwaves oscillated from the microwave oscillator may be within a range of 300 MHz to 10 GHz. For example, by using a magnetron as the microwave oscillator, it is possible to oscillate microwaves having a frequency of 2.45 GHz.

The microwave transmission mechanism 123 is configured to guide the microwaves from the microwave generator 122 to the planar slot antenna 121. The microwave transmission mechanism 123 includes a waveguide 127, a coaxial waveguide 128, and a mode converter 131. The waveguide 127 guides the microwaves from the microwave generator 122 and extends horizontally. The coaxial waveguide 128 includes an inner conductor 129 extending upward from a center of the planar slot antenna 121 and an outer conductor 130 disposed outside the inner conductor 129. The mode converter 131 is provided between the waveguide 127 and the coaxial waveguide 128, and is configured to convert a microwave vibration mode. The microwaves generated by the microwave generator 122 propagate through the waveguide 127 in a TE mode. The vibration mode of the microwaves is converted from the TE mode to a TEM mode by the mode converter 131, and the microwaves are guided to the slow-wave member 126 via the coaxial waveguide 128. Then, the microwaves are radiated from the slow-wave member 126 into the processing container 101 via the slots 121a in the planar slot antenna 121 and the microwave transmission plate 124. A tuner (not illustrated) is provided in the middle of the waveguide 127 to match an impedance of a load (plasma) in the processing container 101 with a characteristic impedance of the power supply of the microwave generator 122.

The gas supply 104 includes a shower plate 141, a shower ring 142, a first gas supply mechanism 162, and a second gas supply mechanism 163.

The shower plate 141 is horizontally provided above the stage 102 in the processing container 101 so as to partition the inside of the processing container 101 vertically. The shower plate 141 includes a gas flow member 151 formed in a grid shape, a gas flow path 152 having a grid shape and provided inside the gas flow members 151, and a plurality of gas ejection holes 153 extending downward from the gas flow path 152. Gaps in the grid-shaped gas flow member 151 are formed as through-holes 154. A gas supply path 155 reaching an outer wall of the processing container 101 extends from the gas flow path 152 of the shower plate 141, and a gas supply pipe 156 is connected to the gas supply path 155.

The shower ring 142 includes a ring-shaped gas flow path 166 provided inside the shower ring 142 and a plurality of gas ejection holes 167 connected to the gas flow path 166 and being open inward of the shower ring. A gas supply pipe 161 is connected to the gas flow path.

The first gas supply mechanism 162 includes a plurality of gas sources for supplying gases, pipes connected to the respective gas sources, and a valve and a flow rate controller provided in the pipes, or the like. The first gas supply mechanism 162 is connected to the shower plate 141 via the gas supply pipe 156.

The second gas supply mechanism 163 includes a plurality of gas sources for supplying gases, pipes connected to the respective gas sources, and a valve and a flow rate controller provided in the pipes, or the like. The second gas supply mechanism 163 is connected to the shower ring 142 via the gas supply pipe 161.

From the first gas supply mechanism 162 and the second gas supply mechanism 163, a plasma generating gas (a rare gas such as Ar gas), a raw material gas for forming a graphene film, a gas for cleaning the interior of the processing container 101, a gas for removing oxygen in the processing container 101 are supplied into the processing container 101 via the shower plate 141 or the shower ring 142. The first gas supply mechanism 162 includes a gas source of a gas that is desired not to be dissociated if possible, such as a raw material gas for forming the graphene film. In addition, the second gas supply mechanism 163 mainly includes a gas source of a gas that is desired to be positively dissociated, such as a rare gas as the plasma generating gas.

In addition, all the gases may be supplied from the shower ring 142 without using the shower plate 141.

The exhauster 105 is configured to evacuate the interior of the processing container 101, and includes the exhaust chamber 111, an exhaust pipe 181 provided in a side surface of the exhaust chamber 111, and an exhaust device 182 connected to the exhaust pipe 181 and including a vacuum pump, a pressure control valve, and the like.

The controller 106 is typically configured with a computer, and controls respective components of the film forming apparatus 200. The controller 106 includes, for example, a storage, which stores a process sequence of the film forming apparatus 200 and process recipes as control parameters, an input part, and a display, and is capable of performing a predetermined control according to a selected process recipe.

As will be described later, in the film forming apparatus 200 as well, all of the cleaning process in the processing container, the oxygen removing process in the processing container, and the film forming process are performed by microwave plasma.

When performing a process with microwave plasma by the film forming apparatus 200, as a plasma generating gas, a rare gas such as Ar gas is supplied from the shower ring 142 to a portion directly under the microwave transmission plate 124 of the processing container 101, and microwaves generated by the microwave generator 122 are radiated into the processing container 101 to ignite plasma. The microwaves generated by the microwave generator 122 are guided to the slow-wave member 126 via the waveguide 127, the mode converter 131, and the coaxial waveguide 128, and are radiated from the slow-wave member 126 into the processing container 101 via the slots 121a in the planar slot antenna 121 and the microwave transmission plate 124.

The microwaves spread as surface waves to a region directly below the microwave transmission plate 124, and surface wave plasma is generated by Ar gas. This region becomes a plasma generation region.

In addition, at the timing at which the plasma is ignited, gases required for the cleaning process, the oxygen removing process, and the film forming process are supplied from the first gas supply mechanism 162 or the second gas supply mechanism 163 via the shower plate 141 or the shower ring 142, thereby performing plasma processes corresponding to these processes.

In this example as well, the plasma generating gas and the processing gases may be simultaneously supplied to the plasma generation region to ignite the plasma, or the processing gases may be supplied to the plasma generation region to ignite the plasma by itself without using the plasma generating gas.

[Film Forming Method]

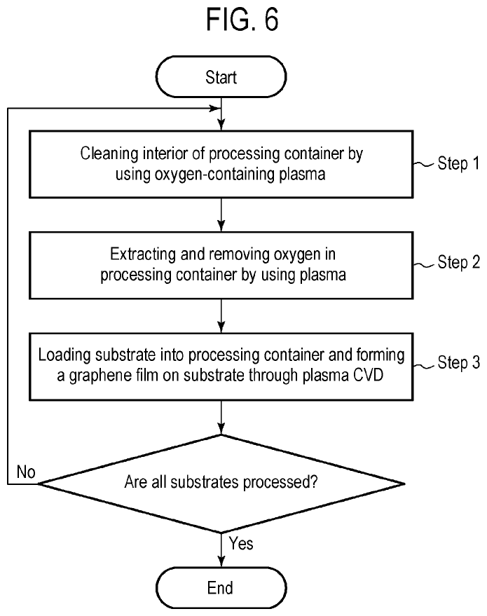

FIG. 6 is a flowchart illustrating a film forming method according to a first embodiment. The film forming method according to the present embodiment is a method of forming a graphene film, which is a carbon film, by a plasma CVD apparatus. The film forming method according to the present embodiment includes a process of cleaning the interior of the processing container by using oxygen-containing plasma (step 1), a process of extracting and removing oxygen in the processing container by using plasma (step 2), and a process of forming the graphene film on a substrate through plasma CVD (step 3). Steps 1 to 3 are repeated until processing of all substrates set in a processing system is completed. These processes are performed according to process recipes stored in a storage of a controller of a film forming apparatus, for example, the controller 6 of the film forming apparatus 100 in the first example or the controller 106 of the film forming apparatus 200 in the second example described above.

Process of Forming Graphene Film through Plasma CVD (Step 3)

In the process of forming a graphene film in step 3, a substrate is placed on a stage in a processing container, a preprocess is performed as necessary, and then the graphene film is formed on the substrate through plasma CVD.

A configuration of the substrate is not particularly limited, but may typically be, for example, a semiconductor substrate (a semiconductor wafer). The semiconductor wafer may be composed of only a semiconductor base made of a semiconductor such as Si, or may have one film of two or more films formed on the semiconductor base. Examples of the films formed on the semiconductor base include an insulating film (SiO₂, SiN, SiCN, SiON, SiOCN, or the like), a silicon film (poly-Si, amorphous Si, or the like which may contain a doping element), or a metallic film (Cu, Co, CoSi, Ni, NiSi, Mo, MoN, W, WN, No, Ru, Hf, Ti, TiN, TiSiN, or the like). The graphene film is formed on the semiconductor base, the insulating film, the silicon film, or the metallic film.

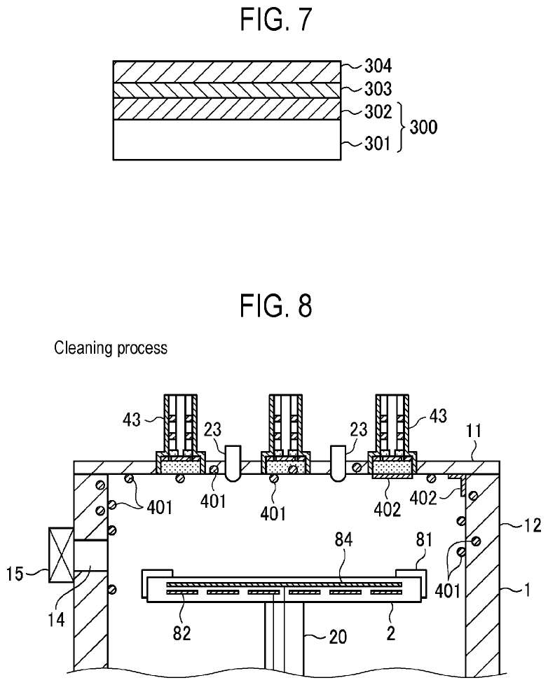

Graphene is a material that has a carbon six-membered ring structure having a dense two-dimensional crystalline structure. Graphene has a quantized conduction characteristic (a ballistic conduction characteristic), and has unique electronic properties such as a current density of 10⁹ A/cm², which is 1,000 times or more that of Cu, and electron mobility of 200,000 cm²/Vs or more, which is 100 times or more that of silicon (Si). In addition, graphene also has a dense and flat atomic structure, high thermal conductivity, and chemical and physical stability. Therefore, it is considered to apply a graphene film to, for example, wiring, a field effect transistor (FET) channel, a contact barrier layer for preventing mutual diffusion of metallic materials, or the like. In particular, since graphene has both a high conductivity and barrier property, graphene is expected to be a material of a thin film barrier layer in place of a metal nitride film (e.g., TiN). As a structure of a semiconductor device when a graphene film is applied to a contact barrier layer, the structure illustrated in FIG. 7 is exemplified. In this structure, a graphene film 303 as a contact barrier layer is formed on a semiconductor wafer 300 in which a poly-Si film 302 is formed on a Si base 301, and a metallic layer 304 (a conductive layer) formed of W, Mo, Ru, Al, Cu, or the like is formed on the graphene film 303. It is important for the contact barrier layer to have both a barrier property and a conductivity with an underlayer. A graphene film is the most appropriate as a contact barrier layer, because it can satisfy both of these properties while providing a barrier layer structure of an ultrathin film.

Prior to the formation of the graphene film, a surface of the substrate may be preprocessed. The preprocessing is performed for the purpose of cleaning and activating the surface of the substrate. For example, the substrate is being processed with plasma while being heated. As a discharge gas, H2 gas or a rare gas such as Ar gas may be used. These gases may be used alone or in combination. A processing temperature and a plasma power may be appropriately set according to a condition of the base.

The graphene film is formed through a plasma CVD method. A carbon-containing gas is used as a processing gas. In addition to the carbon-containing gas, H₂ gas or N₂ gas may be added. In addition, a rare gas may be added as a plasma generating gas or the like. As the rare gas, Ar, He, Ne, Kr, Xe, or the like may be used.

As the carbon-containing gas, a hydrocarbon gas, such as ethylene (C₂H₄), methane (CH₄), ethane (C₂H₆), propane (C₃H₈), propylene (C₃H₆), or acetylene (C₂H₂) may be used.

It is desirable to use microwave plasma as plasma for plasma CVD film formation. Microwave plasma is plasma having a high radical density and low electron temperature. Therefore, the carbon-containing gas may be dissociated into a state appropriate for growth of graphene at a relatively low temperature, and it is possible to directly form the graphene film on the base without damaging the base or the graphene film under formation.

It is desirable to set a temperature (a temperature of the substrate) for forming the graphene film to be 300 degrees C. or higher, and more specifically, 300 to 900 degrees C. In addition, it is desirable to set a pressure in the processing container to be within a range of 4.00 to 53.3 Pa (30 to 400 mTorr). Multiple pressures may be assigned to control spread of plasma.

### Process of Cleaning Interior of Processing Container by Plasma (Step 1)

Due to the formation of the graphene film, carbon adheres to an inner wall of the processing container and forms a carbon film. When the carbon film adhering to the inner wall of the processing container falls off during the formation of the graphene film, the carbon film may be introduced into the graphene film and a film quality may deteriorate. Therefore, the carbon film on the inner wall of the processing container is removed by performing a cleaning process on a regular basis.

In the cleaning process of step 1, in a state in which no substrate to be processes is present in the processing container, an oxygen-containing gas is used as a cleaning gas and the cleaning process is performed by using oxygen-containing plasma. As a result, the carbon film formed on the inner wall of the processing container is oxidized and removed. A plasma source at this time is not particularly limited, and a plasma source used at the time of forming the graphene film may be used, or another plasma source may be used. For example, microwaves, ICP plasma, CCP plasma, remote plasma, or the like may be used as the plasma source. The cleaning process may be performed in a state in which a dummy substrate is placed on the stage. In this case, it is possible to suppress oxidation of a surface of the stage.

As the oxygen-containing gas, O₂, CO, CO₂, or the like may be used. One type or two or more types of oxygen-containing gases may be used. Only the oxygen-containing gas may be used, but a rare gas such as Ar may be added. A desirable example may be cleaning with a gas mixture of Ar and O₂ (Ar—O₂ cleaning). In this case, it is desirable to set a ratio of O₂ relative to Ar to be substantially 1% to 30%.

It is desirable to set a temperature at the time of cleaning to be 300 degrees C. or higher. From the viewpoint of not reducing the throughput, it is desirable to set the temperature at the time of cleaning to be substantially the same as the temperature at the time of forming the graphene film. In addition, it is desirable to set a pressure in the processing container at the time of cleaning to be within a range of 4.00 to 266.6 Pa (30 mTorr to 2 Torr). Multiple pressures may be assigned to control spread of the plasma.

The cleaning process may be performed every film formation on one substrate or every film formation on a plurality of substrates. That is, the process of forming the graphene film in step 3 may include processing one substrate or processing a plurality of substrates repeatedly.

### Process of Extracting and Removing Oxygen in Processing Container by Plasma (Step 2)

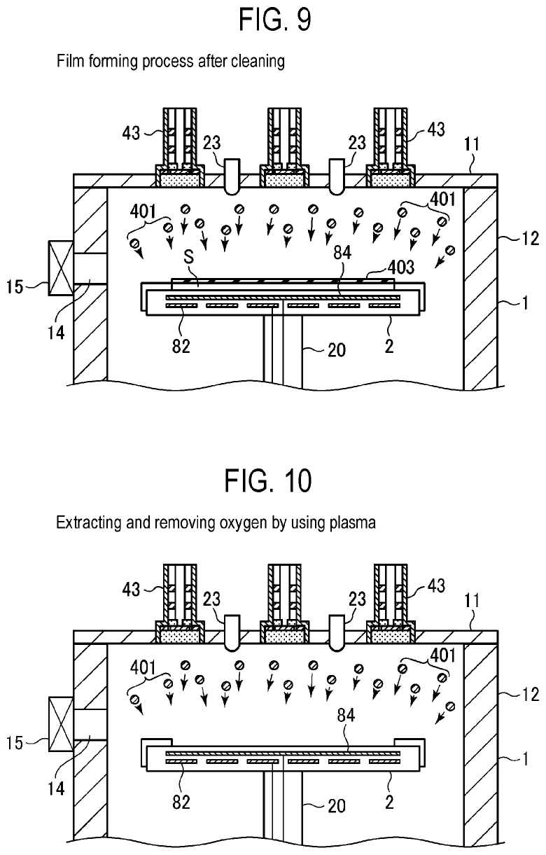

Since the cleaning process by using plasma in step 1 is performed by using an oxygen-containing gas such as O₂, oxygen is introduced into the surface and inside of the inner wall of the processing container by the cleaning process. In addition, oxygen may remain on the surface of the processing container as a reactant by over-oxidizing a base material of the processing container. A schematic view showing this is illustrated in FIG. FIG. 8 is a view illustrating a state in which the film forming apparatus 100 of FIG. 1 has been subjected to a cleaning process, wherein oxygen 401 has been introduced into the surface or inside of the inner wall of the processing container 1 or the base material of the processing container has been over-oxidized to form a reactant 402. Therefore, when the graphene film is formed just after the cleaning process in the film forming apparatus of FIG. 1, as illustrated in FIG. 9, the oxygen 401 is desorbed from the processing container 1 and supplied to the substrate S to form an oxide film 403 on the surface of the substrate S. In addition, oxygen is also introduced into the graphene film itself.

For the reasons described above, in step 2, after the cleaning process, the oxygen in the processing container is extracted and removed by using plasma in the state in which no substrate to be processed is present in the processing container. As illustrated in FIG. 10, in the oxygen extracting and removing process, the oxygen 401 introduced into the surface or inside of the inner wall of the processing container 1 of the film forming apparatus 100 of FIG. 1, or the oxygen 401 in the reactant 402 generated by over-oxidizing the base material of the processing container is extracted by using plasma, and the extracted oxygen is discharged from the processing container 1 by an exhaust device. This process may be performed in the state in which a dummy substrate is placed on the stage in the processing container. By placing the dummy substrate on the stage, it is possible to prevent the surface of the stage from being oxidized by the oxygen extracted by using plasma. In addition, it is possible to reduce plasma irradiation damage on the surface of the stage.

As a gas for forming the plasma for extracting and removing oxygen, for example, a rare gas such as Ar, H₂, N₂, or a halogen-based gas (NF₃, CF, or the like) may be used. These gases may be used alone or two or more of the same may be used in combination. When a rare gas is used, oxygen can be physically cleared by the plasma. In addition, H₂, N₂, NF₃, CF, and the like are reactive gases having reactivity when they are turned into plasma, and oxygen can be extracted by causing a reduction reaction by the plasma of these gases. By using plasma in which a rare gas and a reactive gas are mixed, the effect of extracting oxygen by a physical action and a reduction reaction can be further enhanced. For example, Ar—H₂ plasma and Ar—N₂ plasma may be appropriately used. When a rare gas such as Ar and a reactive gas are mixed, it is desirable to set the reactive gas to be 0.5% or more relative to the rare gas. Here, it is necessary to take care such that the reactive gas is not reintroduced into the carbon film as an impurity after the oxygen is extracted. H₂ is the most appropriate, but as described above, N₂ may be used or a halogen-based gas (F, Cl, Br, I, and a compound thereof) may be used. In addition, plasma of a mixture of three or more gas species, such as an Ar—H₂—N₂ plasma, may be mixed.

It is effective to use a microwave plasma source for the plasma process of extracting and removing oxygen. By using the strong dissociation property of microwaves, it is possible to efficiently excite oxygen in the processing container by plasma, and thus to further enhance the effect of removing oxygen. When a microwave plasma CVD apparatus is used as the film forming apparatus as in the above-described first example or second example, the plasma process for extracting and removing oxygen may be performed by using a microwave plasma source. Even with plasma other than the microwave plasma, the plasma process of extracting and removing oxygen can be performed. For example, ICP plasma, CCP plasma, remote plasma, or the like may be used as a plasma source for extracting and removing oxygen.

By using N₂-containing plasma as the plasma for extracting removing oxygen, it is possible to perform a nitrogen termination process on the inner wall of the processing container, in addition to extracting and removing oxygen. The nitrogen termination process stabilizes a composition of a material of the inner wall of the processing container. When the inner wall of the processing container is not subjected to such a termination process, the inner wall of the processing container is sputtered during plasma CVD of the graphene film, which causes particles. In particular, in the microwave plasma CVD, when the plasma CVD condition becomes a low pressure, sputtering yield energy of the microwaves increases. Thus, sputtering of the inner wall of the processing container intensifies, and particles are likely to be generated. In contrast, when the inner wall of the processing container is subjected to nitrogen termination by N₂ plasma and the composition of the material of the inner wall is stabilized, it is possible to make it difficult for particles to be generated by the sputtering of microwave plasma.

It is desirable to set a temperature at the time of extracting and removing oxygen by using plasma to be 300 degrees C. or higher. From the viewpoint of not reducing the throughput, it is desirable to set the temperature at the time of extracting removing oxygen to be substantially the same as the temperature at the time of forming the graphene film. In addition, it is desirable to set a pressure in the processing container at the time of extracting and removing oxygen by using plasma to be within a range of 6.67 to 266.6 Pa (50 mTorr to 2 Torr). Multiple pressures may be assigned to control the spread of the plasma. By setting the pressure at the time of extracting and removing oxygen by using plasma to be the same as or lower than the pressure at the time of forming a next graphene film, it is possible to further enhance the oxygen removal effect.

The process of extracting and removing oxygen in the processing container by using plasma may use two or more steps. The effect can be enhanced by changing the type or condition of the gas in two or more steps. For example, the steps may include a first step of removing oxygen in the processing container by performing, for example, a process with Ar—H₂ plasma, and a second step of additionally removing oxygen and nitrogen-terminating the inner wall of the processing container by performing a process with N₂-containing plasma. In addition, the process of extracting and removing oxygen may be performed in two or more steps having different pressure conditions during plasma processing. For example, the process of extracting and removing oxygen may be performed as follows. In a first step, Ar—H₂ plasma process is carried out under a low pressure condition of, for example, substantially 30 to 400 mTorr so that oxygen removal is more likely to occur. The reason is because under the low pressure condition, a plasma spread range becomes large so that the oxygen removal effect can be spread over the entire chamber. In a second step, N₂-containing plasma process is carried out under a high pressure condition of, for example, substantially 400 mTorr to 2 Torr. By carrying out the N₂-containing plasma process under a high pressure, it is possible to efficiently perform nitrogen termination on the inner wall of the chamber in the vicinity of the plasma source located in the upper portion of the chamber. It is also possible to change the oxygen removal or nitrogen termination effect by changing a plasma power or a power distribution ratio of a plurality of slugs.

The process of extracting and removing oxygen in the processing container by using plasma may be continuously performed after the cleaning process by integrating a recipe of this process with a recipe of the process of cleaning the interior of the processing container by using plasma of step 1. At this time, after the cleaning process of step 1, by evacuating the interior of the processing container and then performing the process of extracting and removing oxygen in the processing container, the oxygen in the processing container can be easily removed, which enhances efficiency.

In addition, the process of extracting and removing oxygen in the processing container by using plasma may be performed as a preprocess of the process of forming the graphene film of step 3. In a case where a time from the cleaning process to a next film forming process is long, when the process of extracting and removing oxygen is performed continuously after the cleaning process, the interior of the processing container may change over time during a period up to the film forming process after the process of extracting and removing oxygen. In contrast, by performing the process of extracting and removing oxygen as a preprocess of the film forming process, it is possible to prevent such an adverse effect due to the temporal change. Even when the process of extracting and removing oxygen is a preprocess of the film forming process as described above, from the viewpoint of preventing oxidation, the process of extracting and removing oxygen is performed without disposing a substrate in the processing container, i.e., in the state in which no substrate to be processed is present in the processing container or by using dummy substrate.

As described above, by performing the process of extracting and removing oxygen in the processing container after the cleaning process, it is possible to effectively suppress the influence of oxygen, such as oxidation of the surface of the substrate or introduction of oxygen into the film during the subsequent process of forming the graphene film of step 3.

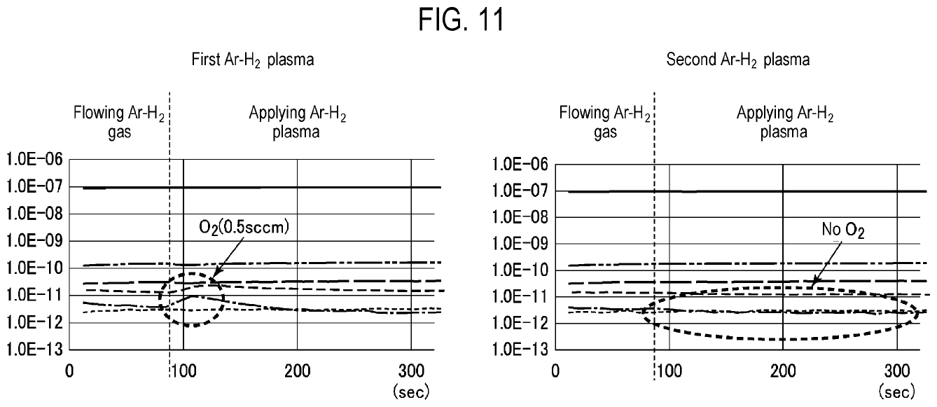

FIG. 11 shows confirmation results of effects when the process of extracting and removing oxygen in the processing container by using plasma has been performed by using Ar—H₂ plasma. FIG. 11 is a view showing results of evaluating an amount of oxygen in the processing container by a quadrupole mass spectrometer (Q-mass) while the process of extracting and removing oxygen in the processing container is performed. Here, after causing Ar—H₂ gas to flow and applying plasma, intensity of O₂ was detected by a Q-mass connected to the processing container. As shown in FIG. 11, O₂ was detected in the first plasma application. That is, the oxygen existing in the processing container was excited and extracted by the Ar—H₂ plasma, and was detected by the Q-mass side connected to the processing container. This is a result directly showing that the oxygen introduced into the surface or inside of the inner wall of the processing container and the oxygen remaining as a reactant by over-oxidizing the base material of the processing container were removed through the Ar—H₂ plasma process. FIG. 11 also shows a result of performing the second plasma application in the same manner after the first plasma application, but O₂ was not detected in the second plasma application. The reason is because O₂ in the processing container was already extracted and removed in the first plasma process. From this, effectiveness of the process of extracting and removing oxygen in the processing container by using plasma in step 2 was confirmed.

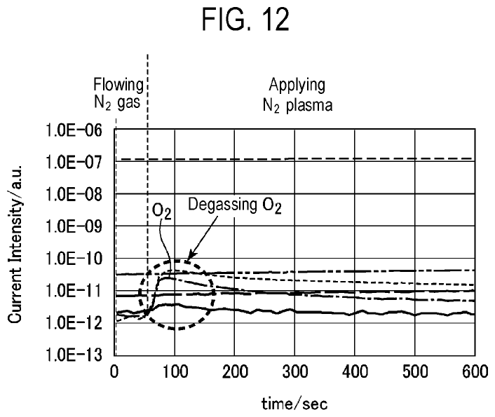

In addition, FIG. 12 shows a confirmation result of effects when the process of extracting and removing oxygen in the processing container by using plasma was performed by using N₂ plasma. Like FIG. 11, FIG. 12 is a view showing a result of evaluating the amount of oxygen in the processing container by a quadrupole mass spectrometer (Q-mass) while the process of extracting and removing oxygen is performed in the processing container. Here, after causing N₂ gas to flow and applying plasma, the intensity of O₂ was detected by a Q-mass connected to the processing container. As shown in FIG. 12, O₂ was detected by applying N₂ plasma. That is, the oxygen existing in the processing container was excited and extracted by the N₂ plasma, and was detected by the Q-mass side connected to the processing container. This is a result directly showing that the oxygen introduced into the surface or inside of the inner wall of the processing container and the oxygen remaining as a reactant by over-oxidizing the base material of the processing container were removed through the N₂ plasma process.

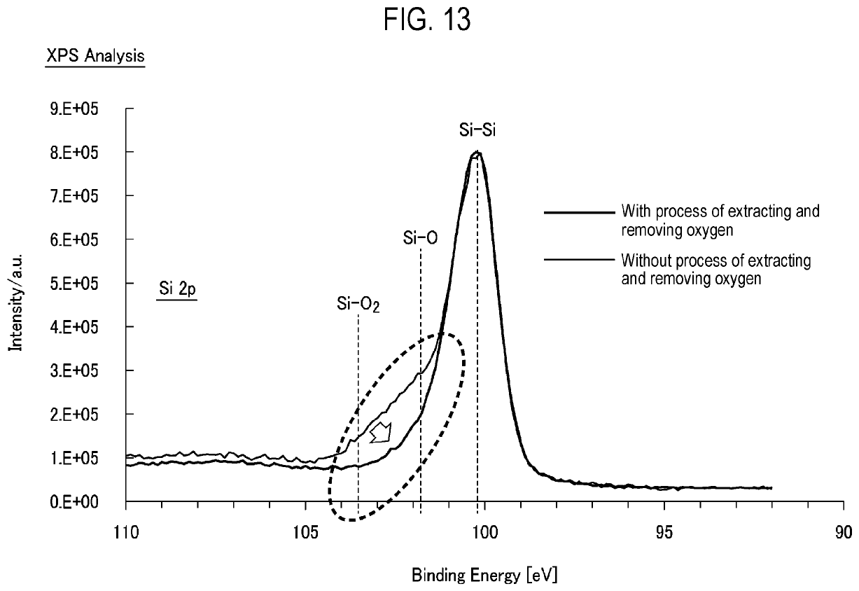

FIG. 13 is a view showing an analysis result of a surface oxidation state of a poly-Si film after a graphene film was formed on a substrate (a wafer) having a poly-Si film formed on a Si base, wherein FIG. 13 illustrates a case in which the process of extracting and removing oxygen was applied and a case in which the process of extracting and removing oxygen was not applied. Here, a Si peak was observed by X-ray photoelectron analysis (XPS). When the surface of the poly-Si film is oxidized, the peak of Si—O or SiO₂ is detected, and a peak intensity in the vicinity of 102 to 104 [eV] increases. As shown in FIG. 13, when the process of extracting and removing oxygen was not applied, peaks of Si—O and SiO₂ appeared, and it can be recognized that surface oxidation of the poly-Si film was present. On the other hand, when the process of extracting and removing oxygen was applied, the peak intensity in the vicinity of 102 to 104 [eV] was low, and it can be recognized that surface oxidation of the poly-Si film was not present, or at least the surface oxidation was suppressed compared to the case in which the process of extracting and removing oxygen was not applied. From this, it was confirmed that the process of extracting and removing oxygen of step 2 is very effective in preventing oxidation of a poly-Si film present on the surface of the substrate.

Such an antioxidation effect is not limited to the case of forming a graphene film on a poly-Si film, but the same can also be obtained in a case of forming a graphene film on a metallic film such as Cu, Co, No, Ru, Hf, Ti, or TiN, as described above. In addition, even when a graphene film is formed on an insulating film, it is possible to prevent properties from changing due to introduction of oxygen into the insulating film, in addition to the antioxidation effect. In any cases, it is possible to prevent or suppress introduction of oxygen into the graphene film.

As described above, when the processing container in which a film forming process is performed uses Al as a base material, an Al₂O₃ film for preventing arcing may be formed on the surface of the film forming apparatus. In addition, a ceramic coat such as Al₂O₃ or Y₂O₃ may be formed on the inner wall of the processing container. In such cases, the process of extracting and removing oxygen in the processing container by using plasma of step 2 becomes more effective. Since the Al₂O₃ film for preventing arcing is formed through anodizing or the like, and the ceramic coat is usually formed on the inner wall of the processing container by a method such as spray irradiation, oxidation by a chemical liquid, or thermal spraying, a plurality of pores or voids are present in the ceramic coat. Since oxygen (O₂) is easily pinned in such pores or voids, the ceramic coat has a structure in which O₂ is likely to remain. In addition, since the ceramic coat is usually a metal oxide, fundamentally, O₂ is easily attracted and over-oxidation is likely to occur in the ceramic coat. Therefore, when forming a graphene film, the influence of oxygen becomes larger. In contrast, by carrying out the process of extracting and removing oxygen in the processing container by using plasma of step 2, it is possible to effectively remove a large amount of O₂ remaining in the ceramic coat so that a more advantageous effect can be obtained.

### Second Embodiment

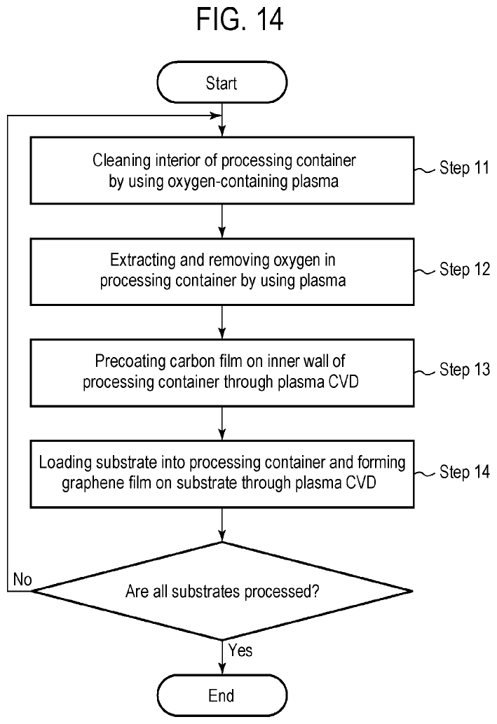

FIG. 14 is a flowchart illustrating a method of forming a graphene film according to a second embodiment. The graphene film forming method according to the present embodiment includes a process of cleaning an interior of a processing container by using oxygen-containing plasma (step 11), a process of extracting and removing oxygen in the processing container by using plasma (step 12), a process of precoating a carbon film on an inner wall of the processing container through CVD (step 13), and a process of forming the graphene film through plasma CVD (step 14). Steps 11 to 14 are repeated until processing of all substrates set in a processing system is completed.

In the present embodiment as well, a plasma CVD apparatus may be used as the film forming apparatus, and the microwave plasma CVD apparatus illustrated in the first example and the second example described above can be appropriately used.

In addition, the process of cleaning the interior of the processing container by using plasma (step 11), the process of extracting and removing oxygen in the processing container by using plasma (step 12), and the process of forming the graphene film through plasma CVD (step 14) may be performed in exactly the same manner as in step 1, step 2, and step 3 of the first embodiment, respectively.

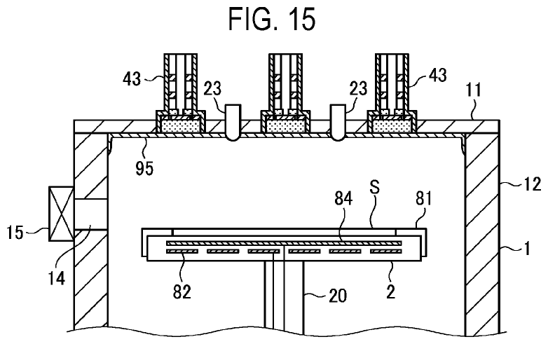

The process of precoating the carbon film on the inner wall of the processing container through plasma CVD of step 13 is a process of forming a film formed of carbon on the inner wall of the processing container in advance in order to protect the inner wall surface of the processing container. In particular, in the case in which the plasma CVD apparatus is a microwave plasma CVD apparatus, when the pressure inside the processing container becomes low, propagation of microwave energy on the inner wall may occur. Thus, the inner wall may be damaged and abnormal discharge may occur. As a countermeasure, there is a method of performing an insulation process by forming a thermal spray coat as a ceramic coat on the inner wall of the processing container. However, under a low pressure, the thermal spray coat on a ceiling wall where plasma energy is high is sputtered and causes particles. Therefore, a carbon film is precoated to protect the inner wall of the processing container. For example, taking the film forming apparatus illustrated in FIG. 1 as an example, as illustrated in FIG. 15, a carbon film 95 is precoated on the inner wall of the ceiling wall 11 of the processing container 1.

When the process of precoating the carbon film of step 13 is performed in a state where oxygen remains on the inner wall of the processing container, oxygen remains in the underlayer, and the remaining oxygen causes oxidation of the surface of the substrate or the like during a subsequent process of forming the graphene film. Therefore, after performing the process of extracting and removing oxygen of step 12, the process of precoating the carbon film of step 13 is performed.

The process of precoating the carbon film is carried out through CVD by using a carbon-containing gas such as a hydrocarbon gas in a state in which no substrate is present in the processing container or a dummy substrate is placed on the stage. A desirable condition at this time is a temperature of 300 degrees C. or higher and a pressure of 4.00 to 266.6 Pa (30 mTorr to 2 Torr).

### <Other Applications>

Although embodiments have been described above, it should be considered that the embodiments disclosed herein are exemplary in all respect and are not restrictive. The above embodiments may be omitted, replaced, or modified in various forms without departing from the scope and gist of the appended claims.

For example, in the above-described embodiments, the case of forming a graphene film as an example has been described, but the present disclosure is not limited to the graphene film, and is also applicable to a case of forming another carbon film such as an amorphous carbon film and a diamond-like carbon film, and the same effect can be obtained.

In the above embodiment, a microwave plasma CVD apparatus is illustrated as an example of a plasma CVD apparatus used as the film forming apparatus, but the present disclosure is not limited to the microwave plasma CVD apparatus. In addition, the configuration of the microwave plasma CVD apparatus is not limited to the above-described examples.

Furthermore, as a substrate for forming a graphene film, a semiconductor wafer having a base of a semiconductor such as Si has been described as an example, but the present disclosure is not limited thereto.

### EXPLANATION OF REFERENCE NUMERALS

1, 101: processing container

2, 102: stage

3, 104: gas supply

4: exhaust device

5: microwave introduction device

6, 106: controller

100, 200: film forming apparatus

103: microwave introduction mechanism

105: exhauster

300: substrate

301: Si base

302: poly-Si film

303: graphene film

304: metallic layer

401: oxygen

S: substrate

1. A film forming method of forming a carbon film, the method comprising:
cleaning an interior of a processing container by using oxygen-containing plasma in a state in which no substrate is present inside the processing container;
subsequently, extracting and removing oxygen inside the processing container by using plasma in a state in which no substrate is present inside the processing container; and
subsequently, loading a substrate into the processing container and forming the carbon film on the substrate through plasma CVD using a processing gas including a carbon-containing gas,
wherein the cleaning, the extracting and removing the oxygen, and the forming the carbon film are repeatedly performed.

2. The film forming method of claim 1, wherein the forming the carbon film is performed through microwave plasma CVD.

3. The film forming method of claim 1, wherein, in the forming the carbon film, a hydrocarbon gas is used as the carbon-containing gas.

4. The film forming method of claim 1, wherein the processing gas when forming the carbon film further includes at least one selected from a rare gas and H₂ gas.

5. The film forming method of claim 1, wherein the carbon film is formed on a surface of a semiconductor base constituting the substrate, or on a surface of a Si film, a metallic film, or an insulating film that are formed on the semiconductor base.

6. The film forming method of claim 1, wherein a graphene film is formed as the carbon film.

7. The film forming method of claim 1, wherein the plasma when extracting and removing the oxygen is plasma of a rare gas, plasma of a reactive gas, or plasma of a mixture of the rare gas and the reactive gas.

8. The film forming method of claim 7, wherein the plasma of the reactive gas contains at least one gas selected from the group of H₂, N₂, NF₃, and CF.

9. The film forming method of claim 8, wherein the plasma when extracting and removing the oxygen is Ar—H₂ plasma or Ar—N₂ plasma.

10. The film forming method of claim 1, wherein the plasma when extracting and removing the oxygen is N₂-containing plasma, and wherein by the plasma, the oxygen in the processing container is extracted and removed and an inner wall of the processing container is nitrogen-terminated.

11. The film forming method of claim 1, wherein the extracting and removing the oxygen is performed by two or more steps in which a gas type or condition is changed.

12. The film forming method of claim 11, wherein the extracting and removing the oxygen includes a first step of removing the oxygen in the processing container, and a second step of additionally removing the oxygen in the processing container and nitrogen-terminating an inner wall of the processing container through a process by using N₂-containing plasma.

13. The film forming method of claim 1, wherein the extracting and removing the oxygen is continuously performed after the cleaning.

14. The film forming method of claim 1, wherein the extracting and removing the oxygen is performed as a preprocess of the forming the carbon film.

15. The film forming method of claim 1, wherein, in the cleaning, the oxygen-containing plasma includes one or two or more of O₂, CO, and CO₂.

16. The film forming method of claim 1, wherein the cleaning is performed by using plasma of an oxygen-containing gas and a rare gas.

17. The film forming method of claim 1, further comprising, after the extracting and removing the oxygen, forming a carbon film on an inner wall of the processing container through plasma CVD using a processing gas including a carbon-containing gas in the state in which no substrate is present in the processing container.

18. A film forming apparatus for forming a carbon film, the apparatus comprising:
a processing container configured to accommodate a substrate and configured to perform a film forming process on the substrate therein;
a plasma source configured to generate plasma in the processing container;
a heater configured to heat an interior of the processing container;
a gas supply configured to supply a gas into the processing container;
an exhauster configured to evacuate the interior of the processing container; and
a controller,
wherein the controller is configured to control the plasma source, the heater, the gas supply, and the exhauster to repeatedly execute:
cleaning the interior of the processing container by using oxygen-containing plasma in a state in which no substrate is present inside the processing container;
subsequently, extracting and removing oxygen inside the processing container by using plasma in the state in which no substrate is present inside the processing container; and
subsequently, loading a substrate into the processing container and forming the carbon film on the substrate through plasma CVD by using a processing gas including a carbon-containing gas.

19. The film forming apparatus of claim 18, wherein the plasma source is a microwave plasma source.

20. The film forming apparatus of claim 19, wherein the controller is further configured to control the plasma source, the heater, the gas supply, and the exhauster to execute, after the extracting and removing the oxygen, forming a carbon film on an inner wall of the processing container through plasma CVD using a processing gas containing a carbon-containing gas in the state in which no substrate is present in the processing container.
